(19) United States
(12) Patent Application Publication
(10) Pub. No.: US 2024/0166083 A1
(43) Pub. Date: May 23, 2024

(54) MOBILE CHARGING SYSTEM WITH BI-DIRECTIONAL DC / DC CONVERTER

(71) Applicant: Electric Power Systems, Inc., North Logan, UT (US)

(72) Inventors: Michael Armstrong, North Logan, UT (US); Nathan Millecam, North Logan, UT (US); Steven Hall, North Logan, UT (US); Randy Dunn, Orange, CA (US); Kurt Rose, North Logan, UT (US)

(73) Assignee: Electric Power Systems, Inc., North Logan, UT (US)

(21) Appl. No.: 18/420,543

(22) Filed: Jan. 23, 2024

Related U.S. Application Data
(63) Continuation of application No. PCT/US2022/038543, filed on Jul. 27, 2022.
(60) Provisional application No. 63/226,086, filed on Jul. 27, 2021.
(60) Provisional application No. 63/244,094, filed on Sep. 14, 2021.
(60) Provisional application No. 63/244,108, filed on Sep. 14, 2021.
(60) Provisional application No. 63/313,640, filed on Feb. 24, 2022.
(60) Provisional application No. 63/313,660, filed on Feb. 24, 2022.

(51) Int. Cl. B60L 58/16; B60L 53/12; B60L 53/57; B60L 53/62; B60L 53/80; B60L 58/12; B64F 1/35; B64F 5/60; H02J 7/34; H02J 50/10

(52) U.S. Cl. CPC B60L 58/16; B60L 53/12; B60L 53/57; B60L 53/62; B60L 53/80; B60L 58/12; B64F 1/352; B64F 5/60; H02J 7/342; H02J 50/10; B60L 2200/10; B60L 2210/10; B60L 2210/30; H02J 2207/20

(57) ABSTRACT

A charging system may comprise: a first battery array; a bi-directional direct current (DC)/DC converter in electrical communication with the first battery array; and a charging interface in electrical communication with the bi-directional DC/DC converter, the charging interface configured to electrically couple to a second battery array of an electric vehicle.

### CROSS-REFERENCE TO RELATED APPLICATIONS

This application is a continuation of PCT Application PCT/US2022/038543 filed Jul. 27, 2022 and titled “MOBILE CHARGING SYSTEM WITH BI-DIRECTIONAL DC/DC CONVERTER” (hereinafter the '543 application). The '543 application claims priority to, and the benefit of, Provisional Patent Application No. 63/226,086, filed Jul. 27, 2021 and titled “MOBILE MICROGRID ECOSYSTEM,” Provisional Patent Application No. 63/244,094, filed Sep. 14, 2021 and titled “MOBILE CHARGING SYSTEM WITH BI-DIRECTIONAL DC/DC CONVERTER,” Provisional Patent Application No. 63,244,108, filed Sep. 14, 2021 and titled “FLUID MANAGEMENT SYSTEM FOR MOBILE CHARGING SYSTEM,” Provisional Patent Application No. 63/313,640, filed Feb. 24, 2022 and titled “CROSS-COMPATIBLE BATTERY MODULES FOR MICROGRID SYSTEMS,” Provisional Patent Application No. 63/313,660, filed Feb. 24, 2022 and titled “COMMON BATTERY MODULES INTERFACES FOR MICROGRID SYSTEMS.” Each disclosure of the foregoing applications is incorporated herein by reference in its entireties, including but not limited to those portions that specifically appear hereinafter, but except for any subject matter disclaimers or disavowals, and except to the extent that the incorporated material is inconsistent with the express disclosure herein, in which case the language in this disclosure shall control.

### FIELD OF INVENTION

The present disclosure generally relates to apparatus, systems and methods for cross-compatible battery modules for multi-integration between mobile charging battery systems and aircraft battery systems.

### BACKGROUND OF THE INVENTION

The subject matter discussed in the background section should not be assumed to be prior art merely as a result of its mention in the background section. Similarly, a problem mentioned in the background section or associated with the subject matter of the background section should not be assumed to have been previously recognized in the prior art. The subject matter in the background section merely represents different approaches, which in and of themselves may be inventions.

A battery module, for purposes of this disclosure, includes a plurality of electrically connected cell-brick assemblies. These cell-brick assemblies may, in turn, include a parallel, series, or combination of both, collection of electrochemical or electrostatic cells hereafter referred to collectively as “cells”, that can be charged electrically to provide a static potential for power or released electrical charge when needed. When cells are assembled into a battery module, the cells are often linked together through metal strips, straps, wires, bus bars, etc., that are welded, soldered, or otherwise fastened to each cell to link them together in the desired configuration.

A cell may be comprised of at least one positive electrode and at least one negative electrode. One common form of such a cell is the well-known secondary cells packaged in a cylindrical metal can or in a prismatic case. Examples of chemistry used in such secondary cells are lithium cobalt oxide, lithium manganese, lithium iron phosphate, nickel cadmium, nickel zinc, and nickel metal hydride. Such cells are mass produced, driven by an ever-increasing consumer market that demands low cost rechargeable energy for portable electronics.

Custom battery solutions may be expensive for a respective customer. Custom battery solutions may include longer lead times due to the customization desired by the customer. Custom battery solutions may be engineering intensive to meet desired characteristics by a customer.

### SUMMARY OF THE INVENTION

A battery system is disclosed herein. The battery system may comprise: a first battery array; a bi-directional direct current (“DC”)/DC converter in electrical communication with the first battery array; and a charging interface in electrical communication with the bi-directional DC/DC converter, the charging interface configured to electrically couple to a second battery array of an electric vehicle.

In various embodiments, the battery system may further comprise: a controller in electronic communication with the bi-directional DC/DC converter, the controller configured to: command the first battery array to charge the second battery array; and command the second battery array to discharge to the first battery array. The controller may be further configured to monitor each battery module in the second battery array during the discharging. The controller may be further configured to determine a state of health of each battery module in the second battery array. The controller may be further configured to determine whether each battery module in the second battery array meets an airworthiness standard based on the state of health. The controller may be further configured to provide an indication to a display device in response to a first battery module in the second battery array no longer meeting the airworthiness standard.

In various embodiments, the battery system may further comprise a second charging interface, a power distribution panel and an alternating current (“AC”)/DC converter. The AC/DC converter may be disposed electrically between the power distribution panel and the second charging interface, and the bi-directional DC/DC converter may be disposed electrically between the power distribution panel and the first battery array.

A control system for an electric vehicle charging system is disclosed herein. The control system may comprise: a processor; and a tangible, non-transitory computer-readable storage medium having instructions stored thereon that, in response to execution by the processor, cause the processor to perform operations comprising: commanding, via the processor and through a bi-directional DC/DC converter a first battery array to charge a second battery array, and commanding, via the processor and through the bi-directional DC/DC converter, the second battery array to discharge to the first battery array.

In various embodiments, the operations further comprise monitoring, via the processor, each battery module in the second battery array during the discharge of the second battery array. The operations may further comprise determining, via the processor, a state of health for each battery module in the second battery array. The operations may further comprise determining, via the processor, whether each battery module in the second battery array meets an airworthiness standard based on the state of health. The operations may further comprise sending an indication to a display device that a first battery module in the second battery array no longer meets the airworthiness standard in response to determining the first battery module in the second battery array no longer meets the airworthiness standard.

A method of charging and commissioning an electric vehicle battery system is disclosed herein. The method may comprise: electrically coupling the electric vehicle battery system to a charging system; charging the electric vehicle battery system through a bi-directional DC/DC converter; discharging the electric vehicle battery system through the bi-directional DC/DC converter; and determining whether each battery module in the electric vehicle battery system exceeds a threshold state of health.

In various embodiments, the threshold state of health is based on an airworthiness standard. The method may further comprise replacing a first battery module with a second battery module in response to the first battery module having a state of health below the threshold state of health. The second battery module may be in a battery system of the charging system. The method may further comprise monitoring each battery module in the electric vehicle battery system during the discharging. The method may further comprise determining a state of health for each battery module in the electric vehicle battery system. The method may further comprise replacing a first battery module in the electric vehicle battery system with a second battery module of the charging system in response to the state of health for the first battery module being below the threshold state of health.

### BRIEF DESCRIPTION OF THE DRAWINGS

A more complete understanding of the present disclosure may be derived by referring to the detailed description and claims when considered in connection with the Figures, wherein like reference numbers refer to similar elements throughout the Figures, and where:

FIG. 1 illustrates a perspective view of a battery system, in accordance with various embodiments;

FIG. 2 illustrates an interconnected battery module for use in a battery system, in accordance with various embodiments;

FIG. 3 illustrates a schematic view of a mobile charging ecosystem, in accordance with various embodiments;

FIG. 4 illustrates a schematic view of a mobile charging ecosystem, in accordance with various embodiments;

FIG. 5 illustrates a schematic view of a portion of a mobile charging ecosystem, in accordance with various embodiments;

FIG. 6 illustrates a method for charging and monitoring an aircraft battery system, in accordance with various embodiments;

FIG. 7A illustrates a schematic view of a portion of a mobile charging ecosystem, in accordance with various embodiments;

FIG. 7B illustrates a schematic view of a portion of a mobile charging system, in accordance with various embodiments;

FIG. 8A illustrates a schematic view of a portion of a mobile charging ecosystem, in accordance with various embodiments;

FIG. 8B illustrates a schematic view of a portion of a mobile charging system, in accordance with various embodiments;

FIG. 9A illustrates a schematic view of a portion of a mobile charging ecosystem, in accordance with various embodiments; and

FIG. 9B illustrates a schematic view of a portion of a mobile charging system, in accordance with various embodiments;

FIG. 10 illustrates a schematic view of a portion of a mobile charging system, in accordance with various embodiments.

### DETAILED DESCRIPTION

The following description is of various example embodiments only, and is not intended to limit the scope, applicability or configuration of the present disclosure in any way. Rather, the following description is intended to provide a convenient illustration for implementing various embodiments, including the best mode. As will become apparent, various changes may be made in the function and arrangement of the elements described in these embodiments, without departing from the scope of the appended claims. For example, the steps recited in any of the method or process descriptions may be executed in any order and are not necessarily limited to the order presented. Moreover, many of the manufacturing functions or steps may be outsourced to or performed by one or more third parties. Furthermore, any reference to singular includes plural embodiments, and any reference to more than one component or step may include a singular embodiment or step. Also, any reference to attached, fixed, connected or the like may include permanent, removable, temporary, partial, full and/or any other possible attachment option. As used herein, the terms “coupled,” “coupling,” or any other variation thereof, are intended to cover a physical connection, an electrical connection, a magnetic connection, an optical connection, a communicative connection, a functional connection, and/or any other connection.

For the sake of brevity, conventional techniques for mechanical system construction, management, operation, measurement, optimization, and/or control, as well as conventional techniques for mechanical power transfer, modulation, control, and/or use, may not be described in detail herein. Furthermore, the connecting lines shown in various figures contained herein are intended to represent example functional relationships and/or physical couplings between various elements. It should be noted that many alternative or additional functional relationships or physical connections may be present in a modular structure.

A “battery array” as described herein refers to a plurality of batteries electrically coupled together. The term “array” is not meant to be limiting as to size, shape, configuration or the like. Any configuration of batteries coupled in series and/or parallel to form a battery system is within the scope of this disclosure.

Disclosed herein is a mobile charging system. Although described herein as a mobile charging system, the present disclosure is not limited in this regard. For example, a fixed charging system may utilize various aspects of the present disclosure and still be within the scope of this present disclosure.

The unique architecture of the mobile charging system disclosed herein enables more energy efficient use of the charging system and the vehicle battery array relative to typical charging systems. The greater efficiency is made possible by implementing a bi-directional direct current (“DC”)/DC converter that is located between a first battery array (e.g., a microgrid battery array) and the vehicle battery array. The bi-directional capability of the charging system enables the converter to act as an adjustable impedance-matching device between the battery arrays. This enables the ability to efficiently power transfer.

The bi-directional DC/DC converter of the mobile charging system disclosed herein reduces an amount of power electronics (i.e., mass and electricity) of the mobile charging system, in accordance with various embodiments. The bi-directional DC/DC converter centralizes a charge control from both an electric vehicle (e.g., an electrically powered aircraft) and the first battery array (e.g., a microgrid battery array). In various embodiments, wireless charging of the microgrid battery array from a utility or wireless charging from the microgrid battery array to the electric vehicle (e.g., an electrically powered aircraft) may be facilitated by the bi-directional DC/DC converter. In various embodiments, the bi-directional DC/DC converter may further allow regeneration of power from the electrically powered aircraft to the microgrid battery array, which may be valuable for maintenance and/or commissioning.

In various embodiments, the bi-directional DC/DC converter disclosed herein may reduce high energy usage and associated cost for typical charging systems. In various embodiments, impedance matching via the bi-directional DC/DC converter may facilitate a wide range of DC input and DC output voltages. In various embodiments, the bi-directional DC/DC converter may enable in-situ battery state of health (“SoH”) and/or battery available capacity determination as described further herein.

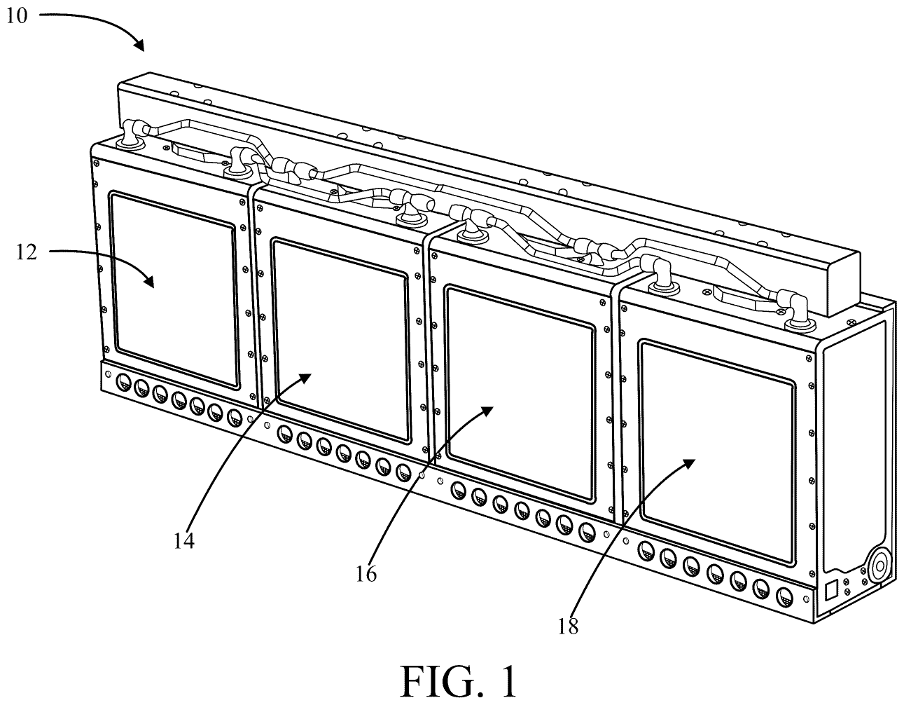

Referring now to FIG. 1, a perspective view of a portion of an interconnected battery system 10 is illustrated, in accordance with various embodiments. In various embodiments, the interconnected battery system 10 includes a plurality of interconnected battery modules (“ICBM” or “ICBMs”) (e.g., interconnected battery modules 12, 14, 16, 18). In various embodiments, each interconnected battery module (e.g., ICBMs 12, 14, 16, 18) includes a plurality of cells disposed therein. The plurality of cells may be cylindrical cells, prismatic cells, pouch cells, or any other cell. In various embodiments, the plurality of cells are a plurality of pouch cells.

In an example embodiment, an ICBM (e.g., ICBMs 12, 14, 16, 18) as disclosed herein may comprise a nominal voltage of approximately 7 volts, a capacity of approximately 50 ampere-hours, an energy output of approximately 0.36 kWh, or the like. Although an example ICBM may have these specifications, an interconnected battery module of any specification is within the scope of this disclosure. For example, an ICBM (e.g., ICBMs 12, 14, 16, 18) as disclosed herein may comprise a nominal voltage of approximately 39 volts, a capacity of approximately 60 ampere-hours, an energy output of approximately 2.3 kWh, or the like. In an example embodiment, a 1,000 volt interconnected battery module system may be created by interconnecting one-hundred and thirty-six ICBMs in series as disclosed herein. In various embodiments, by having each ICBM isolated and discrete from the remaining ICBMs, a thermal runaway event may be limited to a single ICBM where the thermal runaway event occurs. In this regard, in accordance with various embodiments, an ICBM, as disclosed herein, may be configured to contain a thermal runaway event of a cell disposed in the ICBM without affecting any cell in any of the remaining ICBMs.

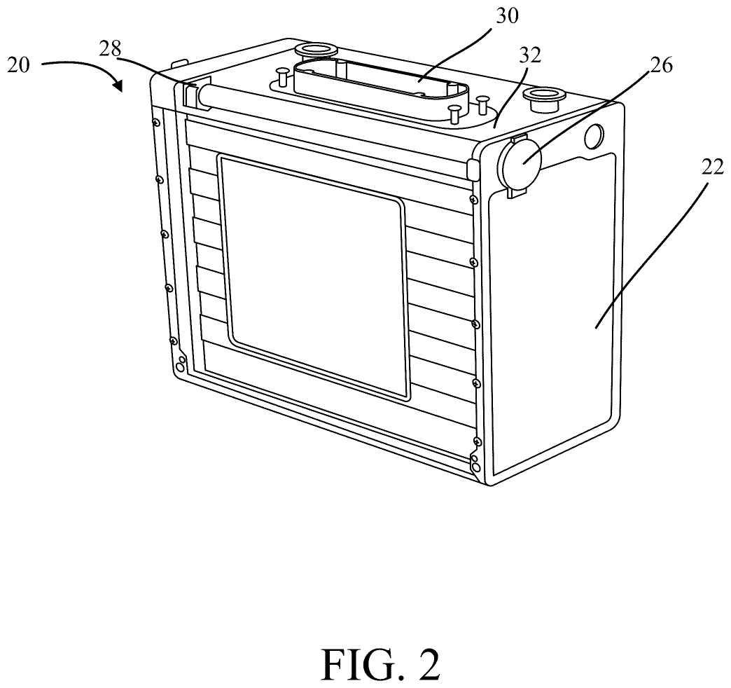

Referring now to FIG. 2, a perspective view of an ICBM 20 is illustrated with a translucent housing, in accordance with various embodiments. In various embodiments the ICBM 20 includes a housing 22 and a plurality of cells disposed in the housing 22. In various embodiments, the plurality of cells are a plurality of pouch cells. In various embodiments, the ICBM 20 includes a positive terminal 26 disposed on a first side of the housing 22 and a negative terminal 28 disposed on a second side of the housing 22.

In various embodiments, the positive terminal 26 is configured to electrically and physically couple to a negative terminal (e.g., negative terminal 28) of an adjacent ICBM in an interconnected battery system (e.g., interconnected battery system 10 from FIG. 1) Similarly, the negative terminal 28 is configured to electrically and physically couple to a positive terminal (e.g., positive terminal 26) of an adjacent ICBM in an interconnected battery system (e.g., interconnected battery system 10 from FIG. 1). In this regard, the ICBMs of interconnected battery system 10 may be configured for electrical and physical coupling in series electrically. However, in other example embodiments, the ICBMs may be configured with an additional component to create a parallel electrical connection, in accordance with various embodiments. The present disclosure is not limited in this regard. For example, the interconnected battery system may be configured to couple adjacent ICBMs in parallel as a default configuration instead of in series as a default configuration and still be within the scope of this disclosure.

In various embodiments, the housing 22 includes a vent port 30. In various embodiments, the vent port 30 is a fluid outlet in the plurality of fluid outlets in an interconnected battery system 10 from FIG. 1. In various embodiments, the vent port 30 is disposed on a top surface of the housing. The vent port 30 is in fluid communication with an internal cavity 32 of the housing 22. The plurality of cells are also disposed in the internal cavity 32. In this regard, any ejecta, gases, or foreign object debris (“FOD”) from a thermal runaway event may be configured to be expelled out the vent port 30 and into a common vent and out of the interconnected battery system (e.g., interconnected battery system 10 from FIG. 1).

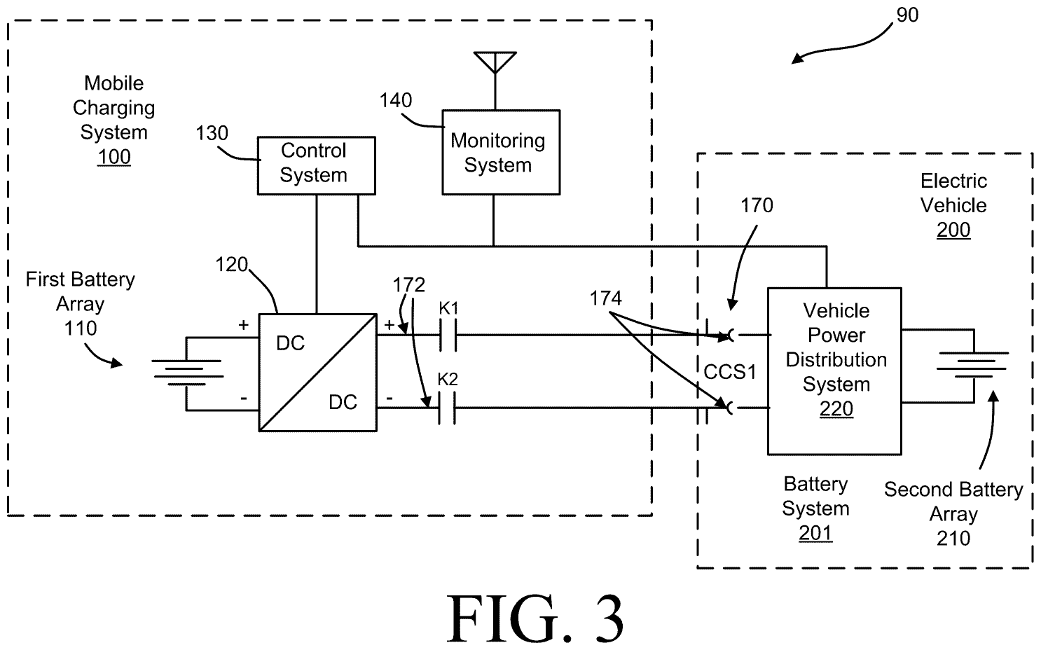

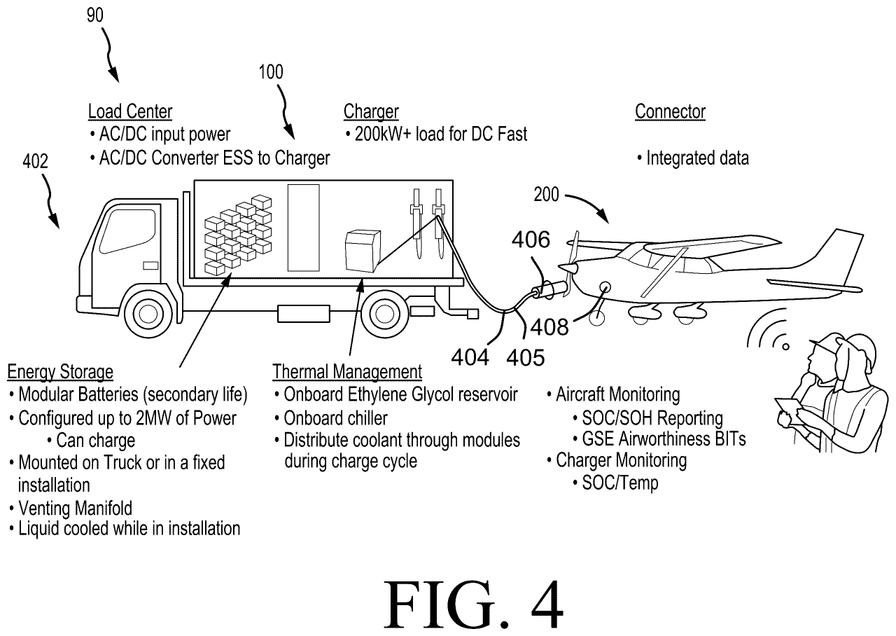

Referring now to FIGS. 3 and 4, a schematic view (FIG. 3) and a side view (FIG. 4) of an electric vehicle charging ecosystem 90 is illustrated, in accordance with various embodiments. The electric vehicle charging ecosystem 90 may be configured for charging an electric vehicle 200 (e.g., an electrically powered aircraft). The electric vehicle charging ecosystem 90 comprises a mobile charging system 100 (e.g. a mobile microgrid) and the electric vehicle 200 having an aircraft battery system 201. The mobile charging system 100 comprises a first battery array 110. Similarly, the electric vehicle 200 comprises the aircraft battery system 201 including a second battery array 210. In various embodiments, the first battery array 110 comprises a plurality of ICBMs (e.g., ICBMs 12, 14, 16, 18) from FIG. 1. In various embodiments, a total energy output for the first battery array 110 may be between 50 kWh and 1.5 MWh, or between 100 kWh and 1 MWh, or approximately 250 kWh.

In various embodiments, the mobile charging system 100 comprises the first battery array 110, a bi-directional DC/DC converter 120, a control system 130, and a monitoring system 140. In various embodiments, the first battery array 110 may be configured to charge the second battery array 210 of the electric vehicle 200. In various embodiments, the first battery array 110 may be configured to be charged via a fixed electrical grid (e.g., configured to receive AC/DC input power) or the like. In various embodiments, the bi-directional DC/DC converter 120 is in operable communication with the control system 130. In this regard, the control system 130 may be configured to control charging of the second battery array 210 by the first battery array 110 through the DC/DC converter 120. The control system 130 may be configured to control discharging of the second battery array 210 through the DC/DC converter 120 to the first battery array 110 as described further herein. Furthermore, the control system 130 may facilitate charging of the first battery array 110 as described further herein.

In various embodiments, the first battery array 110 may be mounted within a vehicle (e.g., a truck or the like as shown in FIG. 4). In various embodiments, the first battery array 110 may be a component of an energy storage system of the mobile charging system 100. In various embodiments, the mobile charging system 100 may further comprise a thermal management system configured to heat or cool the first battery array and/or the second battery array 210 during charging or discharging operations.

In various embodiments, the electric vehicle charging ecosystem 90 comprises a combined charging system (“CCS”) 170 configured for high-power DC fast charging. Although illustrated as comprising a United States style combined charging system (“CCS1”), the charging system is not limited in this regard. For example, the combined charging system 170 may comprise a European style combined charging system (“CCS2”), Chademo, GBT, or any other emerging aerospace standard charging system, in accordance with various embodiments.

In various embodiments, the mobile charging system 100 includes electrical cables 172. The electrical cables 172 extend from the bi-directional DC/DC converter 120 to a combo plug 174 of the combined charging system 170. The combo plug of the combined charging system 170 is configured to be electrically coupled to a socket of the combined charging system 170. In various embodiments, the combo plug is a component of the mobile charging system 100 and the socket is a component of the electric vehicle 200 or vice versa. The present disclosure is not limited in this regard.

In various embodiments, the bi-directional DC/DC converter 120 is configured to act as an impedance matching device. Additionally, the bi-directional DC/DC converter 120 is configured to allow power to be shuttled to and from the second battery array 210 of the aircraft battery system 201 of the electric vehicle 200, thereby enabling advanced battery state of health estimation at every charge cycle, in accordance with various embodiments. Thus, each charge cycle may be an opportunity to assess the SoH and/or capacity of each battery module in the second battery array 210 of the aircraft battery system 201 of the electric vehicle 200 as described further herein. This timely SoH and/or capacity calculation may be utilized to commission each battery module prior to each flight.

In various embodiments, there are two modes facilitated by the bi-directional DC/DC converter. A “charging mode” facilitates charging of the second battery array 210 of the electric vehicle 200 via the first battery array 110 of the mobile charging system 100. In this regard, recharging of the electric vehicle occurs in the charging mode as described further herein. In various embodiments, a “vehicle discharge mode” facilitates discharging of the second battery array 210 into the first battery array 110 through the bi-directional DC/DC converter. In this regard, the vehicle discharging mode supports capacity testing of each battery module (e.g., ICBM 20 from FIG. 2) in the second battery array 210 for battery module commissioning as described further herein.

In this regard, as described further herein, the battery modules of the electric vehicle 200 and the battery modules of the mobile charging system 100 are cross-compatible, in accordance with various embodiments. “Cross-compatible” as defined herein refers to being replaceable with, or swappable with (i.e., a battery module in the second battery array 210 could be swapped with a battery module in the first battery array 110 and vice versa). Although referred to herein as “battery arrays” any system of interconnected battery modules is within the scope of this disclosure. Thus, the term “array” is not a term limiting shape, or configuration, or the like for the battery systems disclosed herein, in accordance with various embodiments. Thus, by commissioning each battery module in the second battery array 210, any battery module that no longer meets an airworthiness standard may be swapped with a battery module in the mobile charging system 100 that meets an airworthiness standard.

In various embodiments, the control system 130 comprises a supervisory control and data acquisition system (“SCADA”). In this regard, the SCADA system may be configured to monitor and control processes of the mobile charging system 100 from a remote location.

In various embodiments, the monitoring system 140 is in operable communication with a vehicle power distribution system 220 in response to the monitoring system 140 being electrically coupled to the vehicle power distribution system 220 or in response to the electric vehicle 200 becoming in range of a wireless network of the monitoring system. In various embodiments, the monitoring system 140 comprises remote telemetry (i.e., a remote telemetry unit (“RTU”) with a microprocessor-based remote device configured to monitor and report events of the vehicle power distribution system 220). The monitoring system 140 may be configured to communicate with the vehicle power distribution system 220 of the electric vehicle 200 through a wireless or wired connection. The present disclosure is not limited in this regard. In various embodiments, the vehicle power distribution system 220 communicates with the monitoring system 140 via a wireless network. In this regard, in response to the vehicle power distribution system 220 becoming in range of the wireless network, the vehicle power distribution system 220 may be configured to transfer information related to operational history of the second battery array 210 to the monitoring system 140. In this regard, battery modules within the second battery array 210 may be continuously monitored for airworthiness, in accordance with various embodiments.

In various embodiments, the vehicle power distribution system 220 is configured to distribute the power from the second battery array 210 to various electrically powered components of the electric vehicle 200 (e.g., an electrical compressor, an electric motor, an electric fan, etc.). In this regard, an electric vehicle 200 may be powered through the vehicle power distribution system 220 utilizing the second battery array 210 of the electric vehicle 200, in accordance with various embodiments. In various embodiments, the vehicle power distribution system 220 is also configured to facilitate charging of the second battery array 210 from the mobile charging system 100.

Referring now to FIG. 4, a schematic view of the electric vehicle charging ecosystem 90 is illustrated, in accordance with various embodiments. The electric vehicle charging ecosystem 90 comprises the mobile charging system 100 and the electric vehicle 200. In various embodiments, the mobile charging system 100 comprises a vehicle 402. The vehicle can comprise any type of vehicle configured to move from one location to another (e.g., a truck, a car, a motorcycle, a plane, a boat, etc.). The present disclosure is not limited in this regard. In various embodiments, the vehicle 402 comprises a motive power system (e.g., an internal combustion engine for a car, a battery system for a car, a hydrogen-powered system, a gas turbine engine for a plane, etc.) and an electrical system (e.g., configured to power electronics within the vehicle 402). In various embodiments, the first battery array 110 described previously herein is electrically isolated from the motive power system and the electrical system.

In various embodiments, the mobile charging system 100 further comprises a charger 404. In various embodiments, the charger 404 comprises a harness 405 and a connector 406. In various embodiments, the harness 405 is configured to house various electrical wiring (e.g., wiring to electrically couple the control system 130 to the vehicle power distribution system 220, the combined charging system 170, etc.) and/or various fluid conduits (e.g., a portion of supply line 152 and/or return line 162). In various embodiments, the connector 406 is configured to couple to a connector of the electric vehicle 200. In this regard, in response to coupling the connector 406 of the mobile charging system 100 to the connector 408 of the electric vehicle 200, the mobile charging system 100 and the electric vehicle 200 are electrically and thermally coupled in the manner shown in FIG. 2A. In this regard, in response to coupling the connector 406 of the mobile charging system 100 to the connector 408 of the electric vehicle 200, the mobile charging system 100 can be configured to facilitate charging of the second battery array 210 of the electric vehicle via the first battery array 110 of the mobile charging system 100 as described previously herein.

In various embodiments, the mobile charging system 100 can be configured to charge multiple electric vehicles 200 simultaneously. In this regard, in various embodiments, the mobile charging system 100 can comprise a plurality of the charger 404. Each charger in the plurality of the charger 404 can be configured to be coupled to an aircraft. In this regard, multiple electric vehicles 200 (e.g., electrically powered aircrafts) can be charged simultaneously, in accordance with various embodiments.

In various embodiments, each charger in a plurality of the charger 404 can comprise an independent battery array (e.g., each charger in a plurality of the charger 404 can be coupled to a battery array 110 that is isolated from an adjacent battery array of a mobile charging system 100). In various embodiments, a single battery array can be utilized with multiple chargers. The present disclosure is not limited in this regard.

In various embodiments, the vehicle power distribution system 220 is configured to distribute the power from the second battery array 210 to various electrically powered components of the electric vehicle 200 (e.g., an electrical compressor, an electric motor, an electric fan, etc.). In this regard, an electric vehicle 200 may be powered through the vehicle power distribution system 220 utilizing the second battery array 210 of the electric vehicle 200, in accordance with various embodiments. In various embodiments, the vehicle power distribution system 220 is also configured to facilitate charging of the second battery array 210 from the mobile charging system 100.

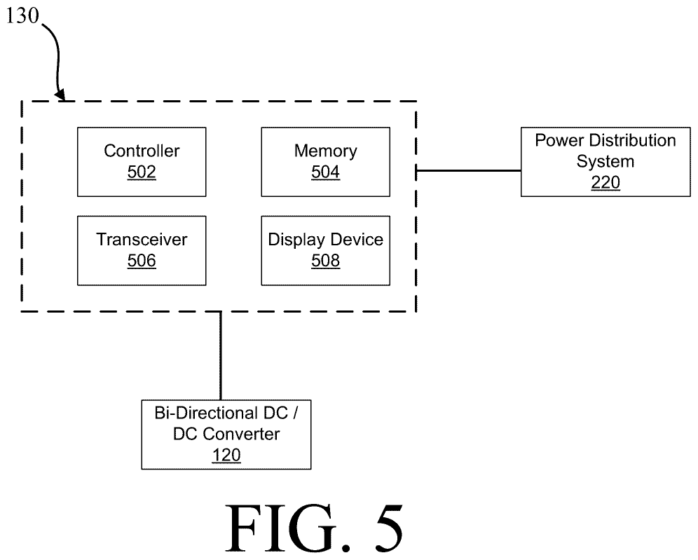

Referring now to FIG. 5, a schematic view of the control system 130 from FIGS. 3 and 4 is illustrated, in accordance with various embodiments. In various embodiments, the control system 130 comprises a controller 502 and a memory 504. In various embodiments, controller 502 may be integrated into computer system of the mobile charging system 100 from FIGS. 3 and 4. In various embodiments, controller 502 may be configured as a central network element or hub to access various systems and components of control system 130. Controller 502 may comprise a network, computer-based system, and/or software components configured to provide an access point to various systems and components of control system 130. In various embodiments, controller 502 may comprise a processor. In various embodiments, controller 502 may be implemented in a single processor. In various embodiments, controller 502 may be implemented as and may include one or more processors and/or one or more tangible, non-transitory memories and be capable of implementing logic. Each processor can be a general purpose processor, a digital signal processor (“DSP”), an application specific integrated circuit (“ASIC”), a field programmable gate array (“FPGA”) or other programmable logic device, discrete gate or transistor logic, discrete hardware components, or any combination thereof. Controller 502 may comprise a processor configured to implement various logical operations in response to execution of instructions, for example, instructions stored on a non-transitory, tangible, computer-readable medium (e.g., memory 504) configured to communicate with controller 502.

System program instructions and/or controller instructions may be loaded onto a non-transitory, tangible computer-readable medium having instructions stored thereon that, in response to execution by a controller, cause the controller to perform various operations. The term “non-transitory” is to be understood to remove only propagating transitory signals per se from the claim scope and does not relinquish rights to all standard computer-readable media that are not only propagating transitory signals per se. Stated another way, the meaning of the term “non-transitory computer-readable medium” and “non-transitory computer-readable storage medium” should be construed to exclude only those types of transitory computer-readable media which were found in In Re Nuijten to fall outside the scope of patentable subject matter under 35 U.S.C. § 101.

In various embodiments, the control system 130 further comprises a transceiver 506 and a display device 508. The transceiver may be configured to communicate with external systems from the control system 130 (e.g., vehicle power distribution system 220 and/or bi-directional DC/DC converter 120). In various embodiments, the bi-directional DC/DC converter 120 may be electrically coupled to the control system 130. The present disclosure is not limited in this regard. In various embodiments, the display device 508 may be in electronic (e.g., wireless or wired) communication with the controller 502. In this regard, in response to a commissioning process (e.g., process 600 described further herein), various data may be presented to various individuals during charging of the electric vehicle 200 from FIGS. 3 and 4 (e.g., an electrically powered aircraft).

Referring now to FIGS. 3, 5, and 6, a process 600 for control system 130 from FIGS. 3, 4, and 5 is illustrated, in accordance with various embodiments. The process 600 comprises commanding, via the controller 502 and through the bi-directional DC/DC converter 120, a first battery array (e.g., the first battery array 110 from FIG. 3), to charge a second battery array (e.g., the second battery array 210 of the electric vehicle 200 from FIG. 3) (step 602). In this regard, the bi-directional DC/DC converter 120 is configured to match the input impedance of the first battery array to an output impedance for charging the second battery array to maximize power transfer and/or minimize signal reflection from the charging.

In various embodiments, the process 600 further comprises commanding, via the controller 502 through the vehicle power distribution system 220, the second battery array 210 to discharge to the first battery array 110 (step 604). In this regard, the bidirectional DC/DC converter 120 is configured to match the input impedance of the second battery array 210 to an output impedance to partially charge the second battery array 210 and test a SoH and/or remaining capacity of each battery module in the second battery array 210. For example, the process 600 further comprises monitoring, via the controller 502, each battery module (e.g., ICBM 20 from FIG. 2) in the second battery array 210 during discharging of the second battery array 210 (step 606). “SoH” as described herein is a measure of each battery modules ability to deliver a specified current when called upon to do so. In this regard, each battery module in the second battery array 210 of the electric vehicle 200 may be monitored to determine whether the battery module has the capability to deliver the specified current. “Remaining capacity” as described herein is a measure of the percentage that is charged of its total capacity to retain charge calibrated to the fuel gauging of the electric aircraft. In various embodiments, the monitoring of step 606 may include monitoring the performance of the second battery array 210 relative to a known discharge profile during the discharging step 604.

Based on the monitoring of step 606, the controller 502 determines an SoH for each battery module in the second battery array (step 608) and determines whether each battery module in the second battery array 210 meets an airworthiness standard based on the SoH (step 610). Thus, the SoH may be measured relative to the specified current, measured impedance, or available capacity. In response to any battery module in the second battery array 210 performing outside allowable thresholds of the airworthiness standard, the controller 502 may determine the battery module is no longer airworthy. Thus, as described previously herein, a battery module from the first battery array 110 may replace the battery module from the second battery array 210 in response to the battery module no longer meeting the airworthiness standard via process 600. Additionally, the battery from the second battery array 210 which no longer meets the airworthiness standard may be removed from the vehicle and integrated into the first battery array 110. Furthermore, the controller 502 may be configured to generate an indication to be output on the display device 508 that a specific battery module in the second battery array 210 no longer meets the airworthiness standard based on the process 600, in accordance with various embodiments.

In various embodiments, when all modules in the second battery array 210 do not exceed a threshold SoH as described previously herein, the controller 502 may communicate the SoH of each battery module in the second battery array 210 to the electric vehicle battery system.

In various embodiments, the controller 502 communicates the SoH or measured capacity of the second battery array 210 to the vehicle power distribution system 220. The capacity may be updated manually (e.g., via an operator), or automatically (e.g., through the control system 130). In this regard, SoH data may be utilized for accurate fuel gauging during operation of the electric vehicle. Thus, calibrated vehicle capacity testing and maintenance action may be facilitated by the control system 130 disclosed herein, in accordance with various embodiments. In various embodiments, the electric vehicle battery system may monitor and record capacity of the second battery array 210 during operation and report to the controller 502 during the process 600. The present disclosure is not limited in this regard.

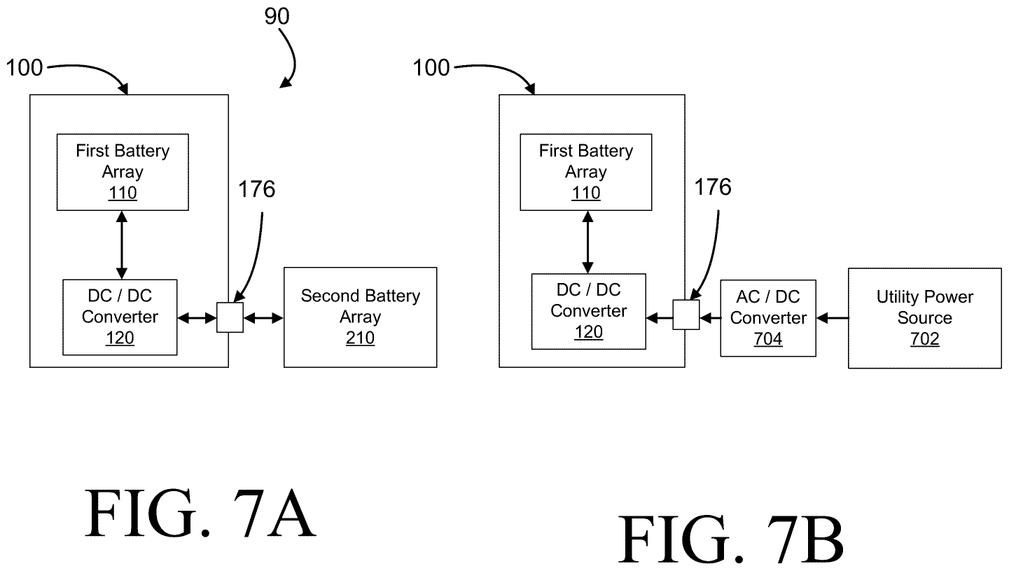

Referring now to FIGS. 7A and 7B, a schematic view of the electric vehicle charging ecosystem 90 (FIG. 7A) and a schematic system of charging of the mobile charging system 100 (FIG. 7B) are illustrated, in accordance with various embodiments. In various embodiments, during charging of the second battery array 210 as shown in FIG. 7A, the bi-directional DC/DC converter 120 is configured to shuttle current from the first battery array 110 to the second battery array 210 in the charging mode described previously herein and shuttle current from the second battery array 210 to the first battery array 110 in the vehicle discharging mode described previously herein. In various embodiments, the mobile charging system 100 comprises a charging interface 176. In various embodiments, the charging interface 176 can be disposed on the connector 406 of the charger 404. In various embodiments, the charging interface 176 can comprise a female port or a male port. The present disclosure is not limited in this regard. The charging interface 176 may be a component of the combined charging system 170 from FIG. 2. In this regard, the charging interface 176 may be a socket configured to receive a combo plug 174 from FIG. 3 or the like. However, separate plugs are within the scope of this disclosure. The present disclosure is not limited in this regard.

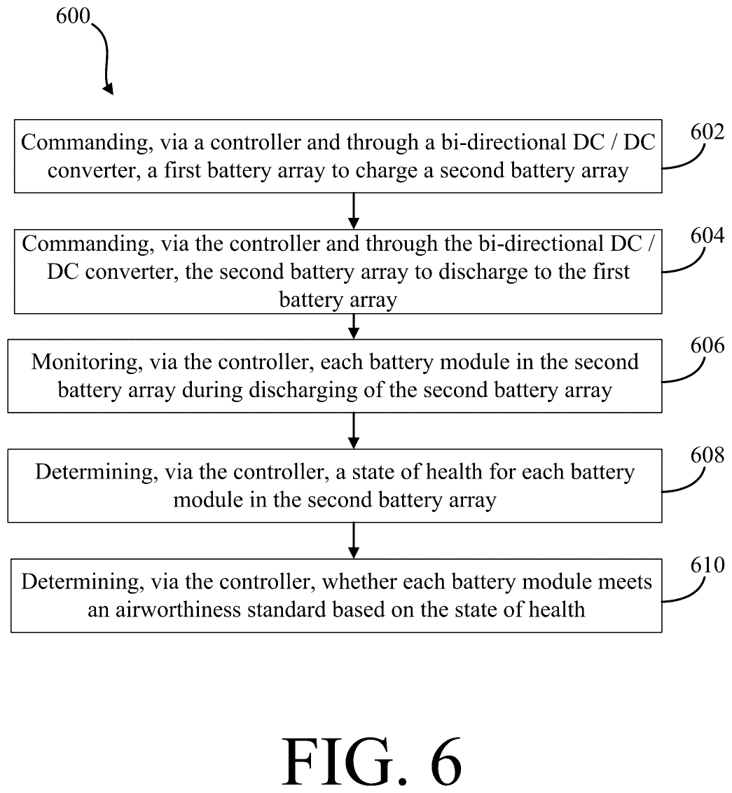

In various embodiments, the mobile charging system 100 is configured to be charged via an alternating current (A/C) source (e.g., a utility power source 702). In this regard, the alternating current provided by the utility power source 702 may be converted via an AC/DC converter 704. In this regard, an AC/DC converter 704 may be electrically coupled to the charging interface 176 of the mobile charging system 100, and the AC/DC converter 704 may be electrically coupled to the utility power source 702 to charge the first battery array 110. In this regard, the common charging interface 176 may be utilized for charging the second battery array 210 via the first battery array 110 (e.g., via step 602 of process 600 from FIG. 6) for discharging the second battery array 210 to the first battery array 110 (e.g., via step 604 of process 600), and for charging the first battery array 110 from the utility power source 702 (FIG. 7B). Thus, the mobile charging system 100 is adaptable for various charging and discharging configurations, in accordance with various embodiments.

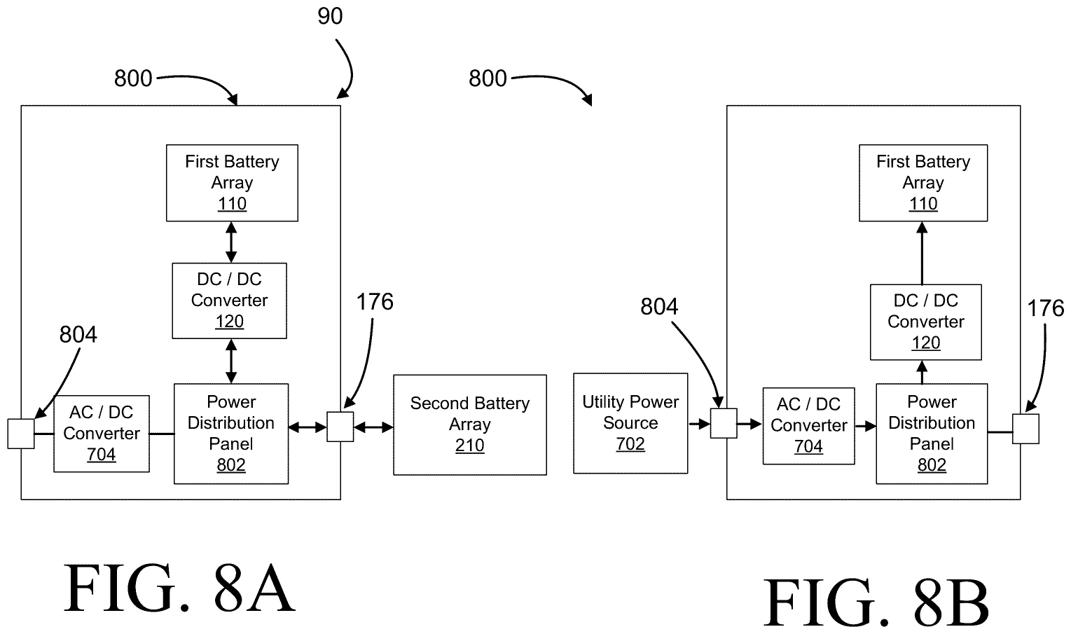

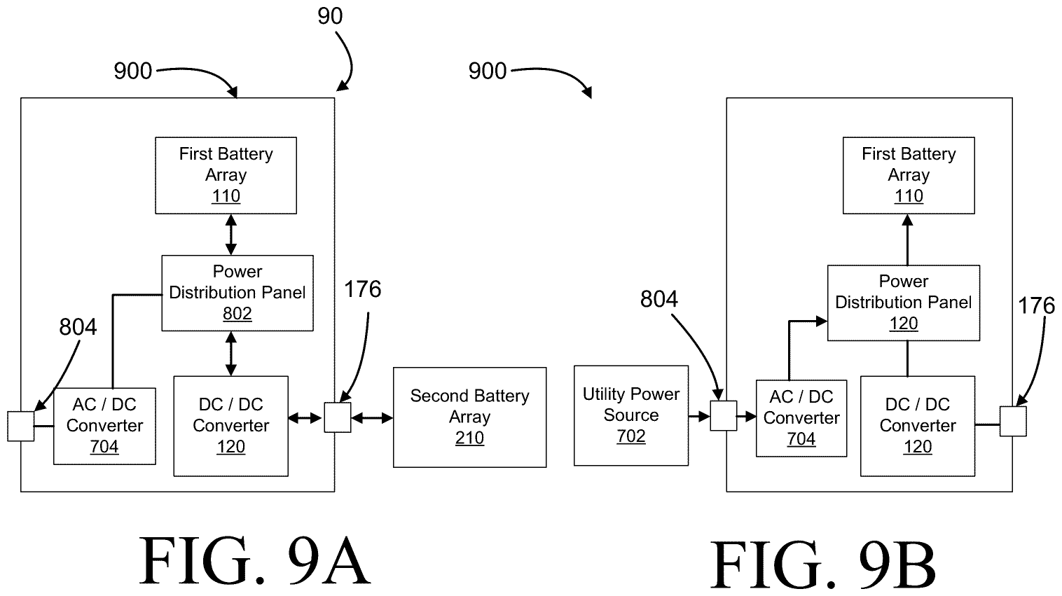

Although illustrated as having the AC/DC converter 704 being external to the mobile charging system 100, the present disclosure is not limited in this regard. For example, with reference now to FIGS. 8A, 8B, 9A, and 9B, schematic views of an electric vehicle charging ecosystem 90 with a mobile charging system 800, 900 (FIGS. 8A, 9A) and schematic systems of the mobile charging system 800, 900 during charging (FIG. 8B, 9B) are illustrated, in accordance with various embodiments. The mobile charging systems 800, 900 may be in accordance with the mobile charging system 100 from FIGS. 3, 4, and 7A-B except as otherwise described herein. The mobile charging system 800 may further comprise the AC/DC converter 704, a power distribution panel 802 and a second charging interface 804. In various embodiments, the power distribution panel 802 may be coupled to the DC converter 120 and be in electrical communication with both the charging interface 176 and the second charging interface 804. In this regard, the power distribution panel 802 is configured to distribute power based on a configuration of the mobile charging system 800.

In various embodiments, the mobile charging system 900 of FIGS. 9A-B may comprise a single electrical interface (e.g., charging interface 176) by orienting the AC/DC converter 704 in parallel with the DC converter 120 between the power distribution panel 802 and the first battery array 110. In various embodiments, mobile charging system 900 may be a simpler configuration relative to mobile charging systems 100, 800 where only one set of power conversions is utilized as long as the AC/DC converter 704 can be controlled (e.g., via power distribution panel 802) to provide variable voltage, power, and current.

For example, with reference now to FIG. 8A in an electric vehicle charging configuration, and in the charging mode described previously herein, the power distribution panel 802 is configured to shuttle voltage, through the bi-directional DC/DC converter 120 from the first battery array 110 to the second battery array 210 in accordance with step 602 of process 600 from FIG. 6. Similarly, in the discharging mode described previously herein, the power distribution panel 802 is configured to shuttle voltage from the second battery array 210, through the bi-directional DC/DC converter 120 to the first battery array 110 during step 604 of process 600 from FIG. 6 described previously herein.

Referring now to FIG. 8B, when the mobile charging system 800 is configured to charge the first battery array 110, the utility power source 702 is electrically coupled to the second charging interface 804. Disposed between the second charging interface 804 and the power distribution panel 802 is the AC/DC converter 704. Thus, the first battery array 110 may be charged by coupling the second charging interface 804 to the utility power source 702 and shuttling an alternating current through the AC/DC converter 704 to the power distribution panel 802, through the bi-directional DC/DC converter 120 to the first battery array 110 of the mobile charging system 800. In various embodiments, the mobile charging system 800 may be advantageous relative to the mobile charging system 100 by having the AC/DC converter 704 as a component of the mobile charging system 800. In contrast, the mobile charging systems 100, 900 may be advantageous relative to the mobile charging system 800 by having a singular charging interface (e.g., charging interface 176) regardless of configuration, and having fewer components. However, mobile charging systems 100, 800, 900 are advantageous over typical charging systems for reasons disclosed previously herein.

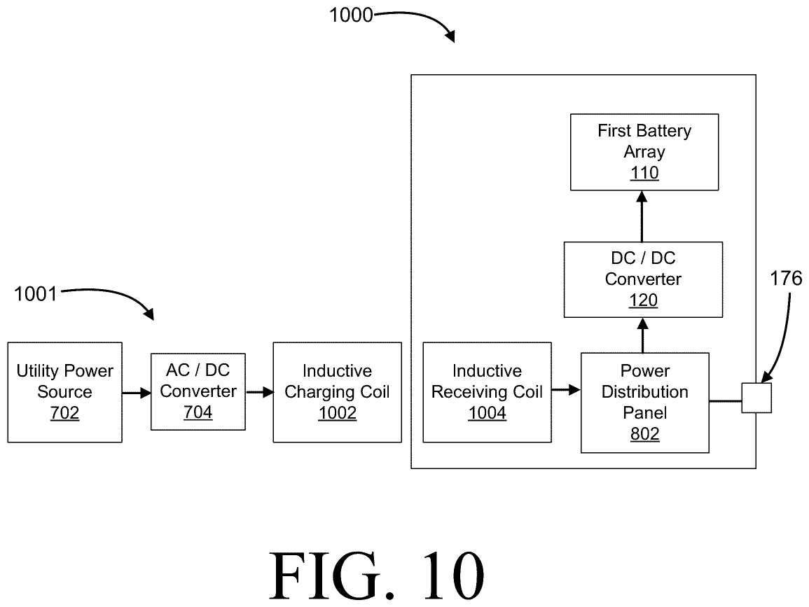

Although illustrated as being configured for wired charging of the first battery array 110, the present disclosure is not limited in this regard. For example, with reference now to FIG. 10, schematic view of a charging system 1001 of the mobile charging system 1000 configured for wireless charging of the first battery array 110 is illustrated in accordance with various embodiments. In various embodiments, the charging system 1001 may comprise an inductive charging coil 1002 in electrical communication with the AC/DC converter 704 and the utility power source 702, all of which are external to the mobile charging system 1000. The mobile charging system 1000 may be in accordance with the mobile charging system 100 except as otherwise described herein. The mobile charging system 1000 may comprise an inductive receiving coil 1004 configured to wirelessly communicate with the inductive charging coil 1002 during charging of the first battery array 110. In this regard, the charging system 1001 may be configured to wirelessly charge the first battery array 110 through the inductive charging coil 1002 and the inductive receiving coil 1004 as illustrated in FIG. 10, in accordance with various embodiments.

While the principles of this disclosure have been shown in various embodiments, many modifications of structure, arrangements, proportions, elements, materials and components (which are particularly adapted for a specific environment and operating requirements) may be used without departing from the principles and scope of this disclosure. These and other changes or modifications are intended to be included within the scope of the present disclosure and may be expressed in the following claims.

The present disclosure has been described with reference to various embodiments. However, one of ordinary skill in the art appreciates that various modifications and changes can be made without departing from the scope of the present disclosure. Accordingly, the specification is to be regarded in an illustrative rather than a restrictive sense, and all such modifications are intended to be included within the scope of the present disclosure. Likewise, benefits, other advantages, and solutions to problems have been described above regarding various embodiments.

However, benefits, advantages, solutions to problems, and any element(s) that may cause any benefit, advantage, or solution to occur or become more pronounced are not to be construed as a critical, required, or an essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

When language similar to “at least one of A, B, or C” or “at least one of A, B, and C” is used in the claims or specification, the phrase is intended to mean any of the following: (1) at least one of A; (2) at least one of B; (3) at least one of C; (4) at least one of A and at least one of B; (5) at least one of B and at least one of C; (6) at least one of A and at least one of C; or (7) at least one of A, at least one of B, and at least one of C.

We claim:

1. A battery system, comprising:
a first battery array comprising a first plurality of battery modules;
a bi-directional direct current (“DC”)/DC converter in electrical communication with the first battery array; and
a charging interface in electrical communication with the bi-directional DC/DC converter, the charging interface configured to electrically couple to a second battery array of an electric vehicle, the second battery array including a second plurality of battery modules.

2. The battery system of claim 1, further comprising a controller in electronic communication with the bi-directional DC/DC, the controller configured to:
command the first battery array to charge the second battery array;
command the second battery array to discharge to the first battery array; and
monitor each of the second plurality of battery modules during the discharging.

3. The battery system of claim 2, wherein the controller is further configured to:
determine a state of health of each of the second plurality of battery modules, based on discharging the second battery array to the first battery array; and
determine whether an airworthiness standard for each of the second plurality of battery modules is met based on the state of health.

4. The battery system of claim 3, wherein the controller is further configured to provide an indication to a display device in response to a first of the second plurality of battery modules no longer meeting the airworthiness standard.

5. The battery system of claim 1, further comprising a second charging interface, a power distribution panel and an alternating current (“AC”)/DC converter, wherein:
the battery system is a charging system,
the AC/DC converter is disposed electrically between the power distribution panel and the second charging interface, and
the bi-directional DC/DC converter is disposed electrically between the power distribution panel and the first battery array.

6. The battery system of claim 1, further comprising an inductive receiving coil in electrical communication with the bi-directional DC/DC converter, the inductive receiving coil configured to wirelessly communicate with an inductive charging coil to charge the first battery array.

7. The battery system of claim 6, further comprising a power distribution panel disposed electrically between the inductive receiving coil and the bi-directional DC/DC converter.

8. A control system for an electric vehicle charging system, the control system comprising:
one or more processors; and
a tangible, non-transitory computer-readable storage medium having instructions stored thereon that, in response to execution by the one or more processors, cause the one or more processors to perform operations comprising:
commanding, by the one or more processors and through a bi-directional direct current (DC)/DC converter a first battery array to charge a second battery array, the first battery array comprising a first plurality of battery modules, the second battery array comprising a second plurality of battery modules, and
commanding, by the one or more processors and through the bi-directional DC/DC converter, the second battery array to discharge to the first battery array.

9. The control system of claim 8, wherein the operations further comprise monitoring, by the one or more processors, each of the second plurality of battery modules during the discharge of the second battery array.

10. The control system of claim 9, wherein the operations further comprise determining, by the one or more processors, a state of health for each of the second plurality of battery modules.

11. The control system of claim 10, wherein the operations further comprise determining, by the one or more processors, whether an airworthiness standard for each of the second plurality of battery modules is met based on the state of health.

12. The control system of claim 11, wherein the operations further comprise sending, by the one or more processors, an indication to a display device that a first of the second plurality of battery modules no longer meets the airworthiness standard in response to determining the first of the second plurality of battery modules no longer meets the airworthiness standard.

13. A method of determining charging and commissioning an electric vehicle battery system, the method comprising:
electrically coupling the electric vehicle battery system to a charging system, the electric vehicle battery system comprising a first plurality of battery modules, the charging system comprising a second plurality of battery modules;
charging the electric vehicle battery system through a bi-directional DC/DC converter;
discharging the electric vehicle battery system through the bi-directional DC/DC converter;
determining a state of health for each of the first plurality of battery modules based on the discharging; and
determining whether the state of health for each of the first plurality of battery modules of the electric vehicle battery system exceeds a threshold state of health.

14. The method of claim 13, wherein the threshold state of health is based on an airworthiness standard.

15. The method of claim 13, further comprising replacing a first of the first plurality of battery modules with a first of the second plurality of battery modules in response to the of the first plurality of battery modules having a first state of health below the threshold state of health.

16. The method of claim 15, wherein the first of the second plurality of battery modules is in a battery system of the charging system.

17. The method of claim 13, further comprising monitoring each of the first plurality of battery modules of the electric vehicle battery system during the discharging.

18. The method of claim 17, further comprising:
determining a state of charge for each of the first plurality of battery modules of the electric vehicle battery system; and
replacing a first of the first plurality of battery modules in the electric vehicle battery system with a first of the second plurality of battery modules of the charging system in response to the state of health for the first of the first plurality of battery modules being below the threshold state of health.

19. The method of claim 13, further comprising measuring a capacity of the electric vehicle battery system during the discharging.

20. The method of claim 13, further comprising monitoring a performance of the electric vehicle battery system relative to a known discharge profile during the discharging.
